(19) United States
(12) Patent Application Publication
(10) Pub. No.: US 2026/0248029 A1
(43) Pub. Date: Aug. 20, 2026

(54) PROTECTIVE OPEN TOP PACKAGE FOR SEMICONDUCTOR DIE

(71) Applicant: Micron Technology, Inc., Boise, ID (US)

(72) Inventors: Travis Michael JENSEN, Boise, ID (US); Bradley Russell BITZ, Taichung City (TW)

(21) Appl. No.: 19/424,251

(22) Filed: Dec. 18, 2025

Related U.S. Application Data
(60) Provisional application No. 63/759,859, filed on Feb. 18, 2025.

(51) Int. Cl. H10W 74/10; H10W 40/20; H10W 74/01; H10W 74/15; H10W 90/00

(52) U.S. Cl. CPC H10W 74/141; H10W 40/242; H10W 74/016; H10W 74/15; H10W 90/736; H10W 90/724; H10W 90/754

(57) ABSTRACT

A semiconductor device assembly includes a circuit substrate comprising a first substrate surface; a semiconductor die arranged on, and electrically coupled to, the first substrate surface, the semiconductor die having a first die surface that faces away from the first substrate surface, a second die surface that faces toward the first substrate surface, and die edges that extend between the first and second die surfaces; and a package casing disposed over the first substrate surface, and partially encapsulating the semiconductor die. The package casing encapsulates the die edges and at least part of the first substrate surface, and includes one or more raised portions that cover an edge region of the first die surfaces. The first die surface includes one or more exposed portions that are not covered by the package casing, and are configured to dissipate heat generated by the semiconductor die.

### CROSS-REFERENCE TO RELATED APPLICATION

This Patent Application claims priority to U.S. Provisional Patent Application No. 63/759,859, filed on February 18, 2025, entitled “PROTECTIVE OPEN TOP PACKAGE FOR SEMICONDUCTOR DIE,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a protective open top package for a semiconductor die.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1A shows a semiconductor device assembly according to one or more implementations.

FIG. 1B shows a semiconductor device assembly according to one or more implementations.

FIG. 2A shows a semiconductor device assembly according to one or more implementations.

FIG. 2B shows a semiconductor device assembly according to one or more implementations.

FIG. 3A shows an isometric view of a semiconductor device assembly having an embossed pattern according to one or more implementations.

FIG. 3B shows an isometric view of a semiconductor device assembly having an embossed pattern according to one or more implementations.

FIG. 3C shows an isometric view of a semiconductor device assembly having an embossed pattern according to one or more implementations.

FIG. 3D shows an isometric view of a semiconductor device assembly having an embossed pattern according to one or more implementations.

FIGS. 4A-4D show an example process for manufacturing a semiconductor device assembly according to one or more implementations.

FIGS. 5A-5C show an example process for manufacturing a semiconductor device assembly according to one or more implementations.

### DETAILED DESCRIPTION

The semiconductor industry constantly faces thermal management challenges, especially as devices become smaller and more power-hungry. The efficient dissipation of heat is critical to maintain the performance and longevity of semiconductor components. In multi-stacked package designs that offer higher capacity within the same footprint, managing the heat generated becomes increasingly complex. Thermal issues are exacerbated by the need for packaging technologies to protect certain areas of a semiconductor die, such as die edges and corners, and to prevent die and/or package warpage.

Some traditional encapsulation processes provide additional non-functional layers of silicon to protect the delicate wire bond connections and a semiconductor die. Such layers introduce additional manufacturing steps, contributing to increased complexity and production costs.

Some traditional encapsulation processes may leave die edges and corners of a semiconductor die exposed, which may elevate the risk of chipping or breakage at the die edges and corners. Moreover, the semiconductor die may be more susceptible to warpage and/or separation from the encapsulation. The complexities of these encapsulation techniques, combined with the intrinsic value of protecting the die surface and edges, underscore the necessity for an encapsulation approach that can effectively manage heat generated by a semiconductor die, while also providing protection to the semiconductor die from damage and/or warpage.

Implementations described herein relate to various semiconductor device assemblies and to a technical advancement in thermal management for semiconductor device assemblies through an innovative encapsulation process. The semiconductor device assembly may include a semiconductor die situated on a circuit substrate, with a package casing partially encapsulating the semiconductor die. The design of the package casing features raised (elevated) portions that overlay the edges of the semiconductor die, deliberately leaving areas of the semiconductor die's top surface unobstructed to facilitate heat dissipation. The raised portions of the package casing cover an edge region of the semiconductor die's top surface that is adjacent to the edges of the semiconductor die. In some implementations, the package casing may form a bezel around the semiconductor die. This architecture leverages embossed mold clamp tooling, which precisely shapes a mold compound of the package casing during manufacture to form the raised portions of the package casing and predetermined heat-dissipation zones on the semiconductor die's top surface, thereby omitting the need for supplementary non-functional silicon layers. The predetermined heat-dissipation zones may be exposed portions or regions of the semiconductor die's top surface that allow heat to dissipate from the semiconductor die to a heat dissipation medium.

Additionally, various embossed patterns such as windowpane, waffle, or checkered configurations can be utilized for tailoring exposure of specific die hotspots to an ambient environment. When combined with a thermal interface material (TIM) and a heat spreader, these designs may significantly augment cooling efficiency. The encapsulation methodology may also accommodate different types of chip-on-board (COB) packages, including wire bond packages, face-down packages, face-up packages, and flip chip packages, while exempting the requirement for surplus dummy layers, thus enhancing the simplicity and dependability of the packaging process.

In this way, the semiconductor device assembly and method of manufacture specifically address the technical demands associated with the dissipation of heat from increasingly compact and high-power-consuming semiconductor dies. By selectively covering a semiconductor die and concurrently ensuring strategic areas remain uncovered to enable heat dissipation, the proposed solution not only safeguards the semiconductor die but also promotes efficient thermal management. The semiconductor device assembly and method of manufacture may permit semiconductor devices to safely function at elevated capabilities within unchanged frameworks. In this way, quality and/or reliability of the semiconductor device may be improved.

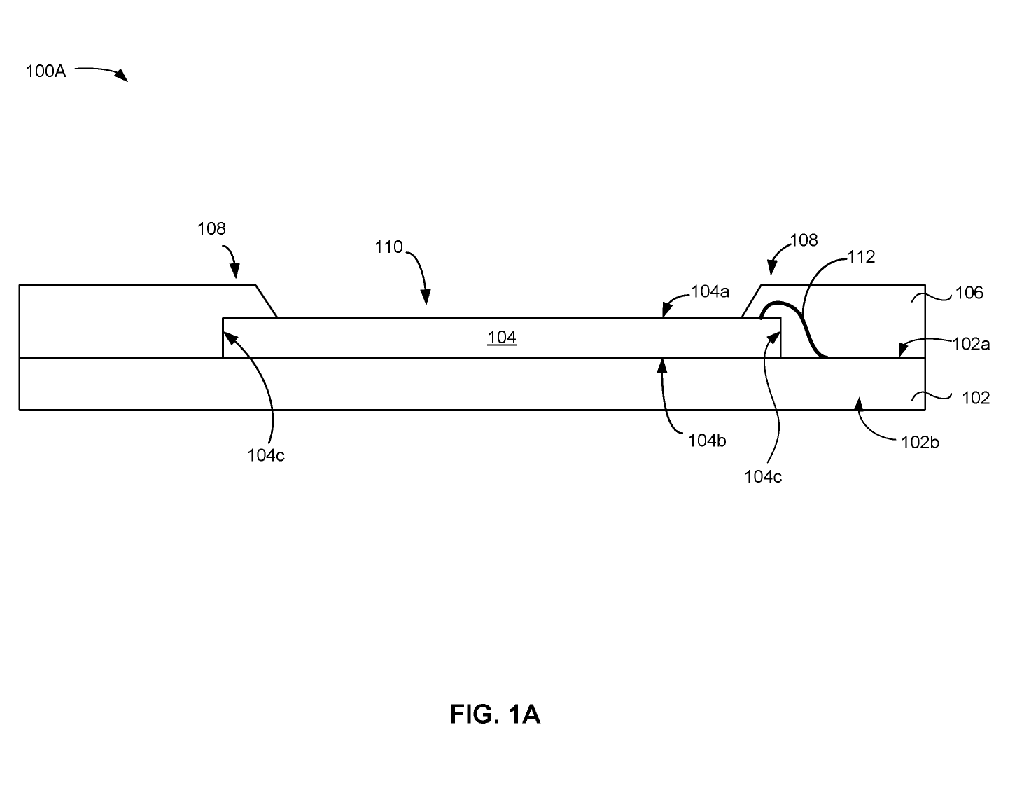

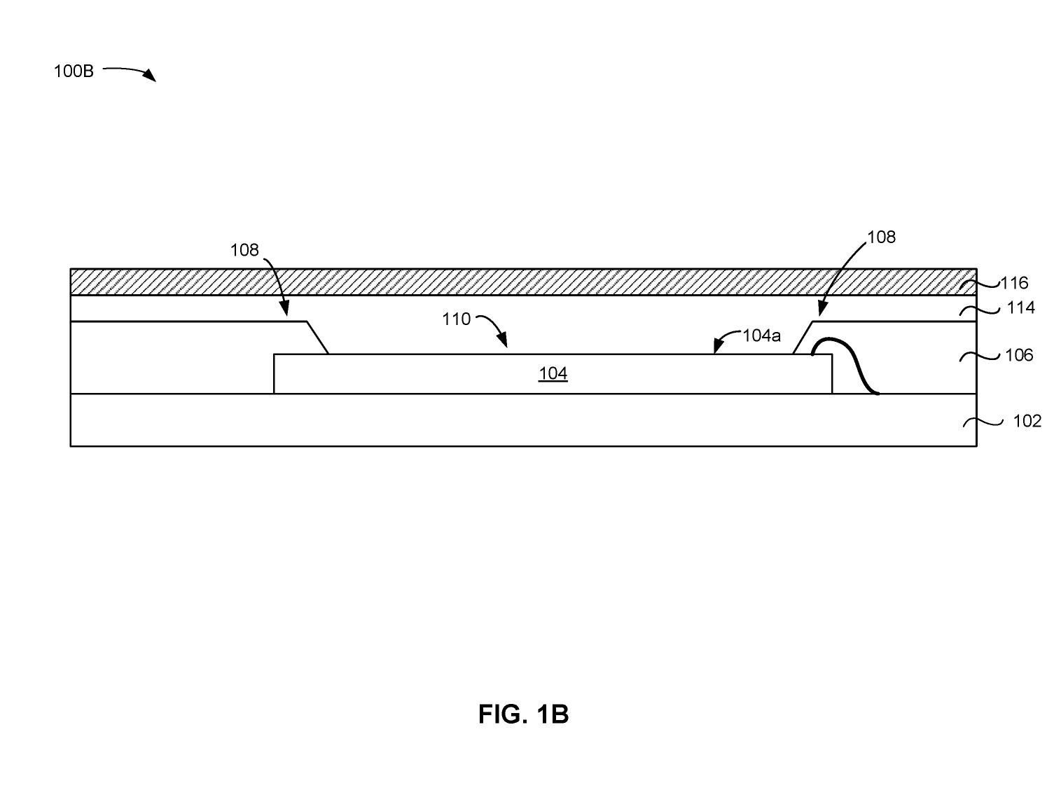

FIG. 1A shows a semiconductor device assembly 100A according to one or more implementations. The semiconductor device assembly 100A may include a circuit substrate 102, a semiconductor die 104, and a package casing 106.

The circuit substrate 102 may be a printed circuit board (PCB) on which the semiconductor die 104 and the package casing 106 are mounted. Thus, the circuit substrate 102 may include a first substrate surface 102a (e.g., a top substrate surface) and a second substrate surface 102b (e.g., a bottom substrate surface) arranged opposite to the first substrate surface 102a.

The semiconductor die 104 may be arranged on, and electrically coupled to, the first substrate surface 102a of the circuit substrate 102. The semiconductor die 104 may include a first die surface 104a (e.g., a top die surface) that faces away from the first substrate surface 102a, a second die surface 104b (e.g., a bottom die surface) that faces toward the first substrate surface 102a, and die edges 104c that extend between the first die surface 104a and the second die surface 104b. In some implementations, multiple semiconductor dies 104 may be arranged on the first substrate surface 102a of the circuit substrate 102. The multiple semiconductor dies 104 may be laterally spaced apart on the first substrate surface 102a, or may be stacked vertically to form a die stack.

The package casing 106, such as a package molding, may be disposed over the circuit substrate 102. For example, the package casing 106 may be disposed over the first substrate surface 102a in order to partially encapsulate the semiconductor die 104 and to protect the semiconductor die 104 from damage and/or warpage. The package casing 106 may encapsulate the die edges 104c and at least part of the first substrate surface 102a of the semiconductor die 104. The package casing 106 may include one or more raised portions 108 that cover an edge region of the first die surface 104a that is adjacent to the die edges 104c. The package casing 106 may cover the edge region in a smooth and seamless manner, which is an outcome of forming package casing 106 using an embossed top mold. Surfaces of the package casing 106 are smooth, especially when compared to techniques that involve first forming a package casing and removing portions of the package casing after the package casing has been cured. Techniques that involve first forming a package casing and removing portions of the package casing after the package casing has been cured leave rough traces of the removal. Thus, the surfaces of the package casing 106, including the outer surfaces adjacent to an aperture, have a high-degree of smoothness (e.g., completely smooth with uniform smoothness). In some implementations, the raised portions 108 may be sloped to smoothly transition into the first die surface 104a.

Additionally, the first die surface 104a may include one or more exposed portions 110 (exposed regions or apertures) that are not covered by the package casing 106. The one or more exposed portions 110 may be configured to dissipate heat generated by the semiconductor die 104. In some implementations, the package casing 106 may form a bezel around the semiconductor die 104. In some implementations, the package casing 106 may hook around the die edges 104c to extend over the edge region of the first die surface 104a. In some implementations, the package casing 106 may be formed as a one-piece molding made of a mold compound. Thus, the package casing 106 may protect the die edges 104c and the edge region of the first die surface 104a, including corners of the semiconductor die 104.

The package casing 106 and the one or more exposed portions 110 may be formed according to an embossed pattern over the first die surface 104a. For example, the embossed pattern may a windowpane pattern, a waffle pattern, a checkered pattern, or an I-shaped pattern. In some implementations, the one or more exposed portions 110 may be formed over respective hotspots of the semiconductor die 104 to efficiently dissipate heat from the semiconductor die 104, while the package casing 106 may be formed over regions of the semiconductor die 104 that are less critical for thermal management. The respective hotspots may correspond to active circuit areas within the semiconductor die 104. In addition, the package casing 106 may be formed at regions of the semiconductor die 104 to optimize structural support and warpage prevention of the semiconductor die 104. Thus, the embossed pattern may be configured to optimize or otherwise balance the needs for thermal management, by way of heat dissipation, and structural support and protection.

In some implementations, the semiconductor device assembly 100A may include one or more bond wires 112 connected to the edge region of the first die surface 104a and to the first substrate surface 102a. In other words, the one or more bond wires 112 may electrically connect the semiconductor die 104 to one or more conductive traces of the circuit substrate 102. The one or more bond wires 112 may be entirely encapsulated by the package casing 106. For example, the one or more raised portions 108 of the package casing may protect the one or more bond wires 112. In some implementations, the second die surface 104b may be arranged directly on the first substrate surface 102a.

As indicated above, FIG. 1A is provided as an example. Other examples may differ from what is described with regard to FIG. 1A.

FIG. 1B shows a semiconductor device assembly 100B according to one or more implementations. The semiconductor device assembly 100B may be similar to the semiconductor device assembly 100A described in connection with FIG. 1A. The semiconductor device assembly 100B may further include a TIM layer 114 and a heat spreader layer 116.

The TIM layer 114 may be arranged over the first die surface 104a such that the TIM layer 114 is in contact with the one or more exposed portions 110 of the semiconductor die 104 and the one or more raised portions 108 of the package casing 106. In some implementations, the TIM layer 114 may be arranged over the one or more raised portions 108 of the package casing 106.

The heat spreader layer 116 may be arranged on the TIM layer 114 such that the TIM layer 114 is arranged between the heat spreader layer 116 and the first die surface 104a. Thus, the heat spreader layer 116 may be thermally coupled to the one or more exposed portions 110 by the TIM layer 114. The TIM layer 114 and the heat spreader layer 116 may be configured to receive heat from the one or more exposed portions 110 and move the heat away from the semiconductor die 104.

As indicated above, FIG. 1B is provided as an example. Other examples may differ from what is described with regard to FIG. 1B.

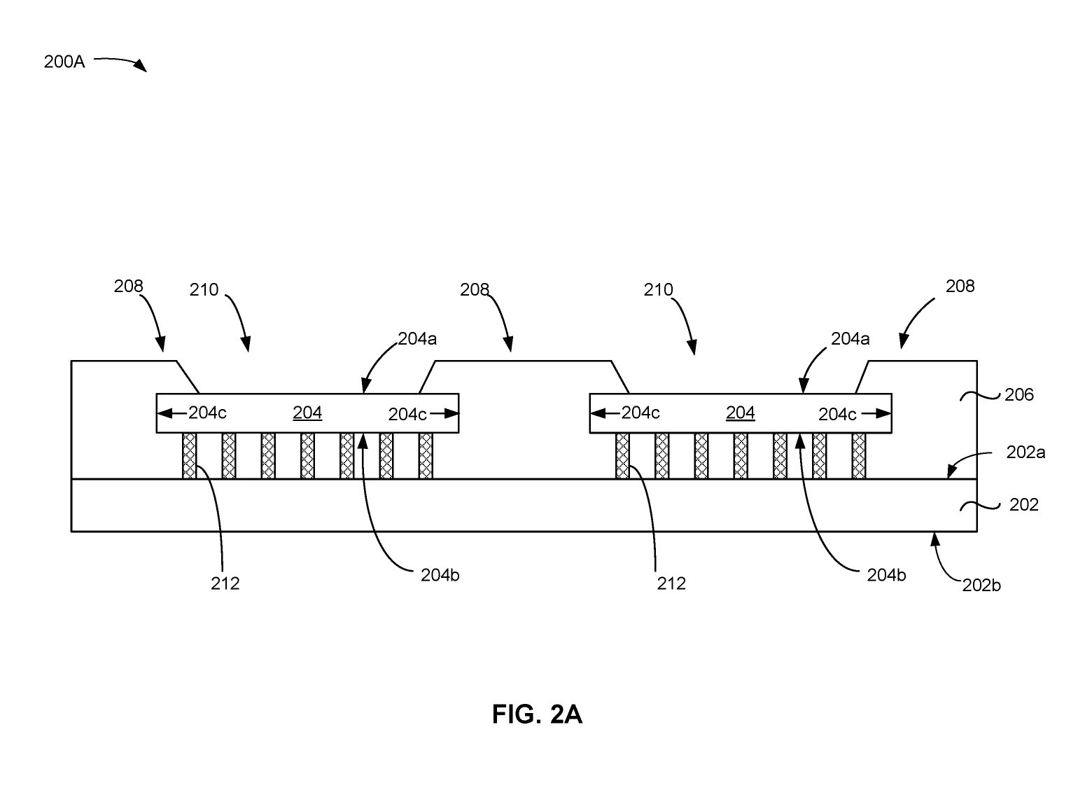

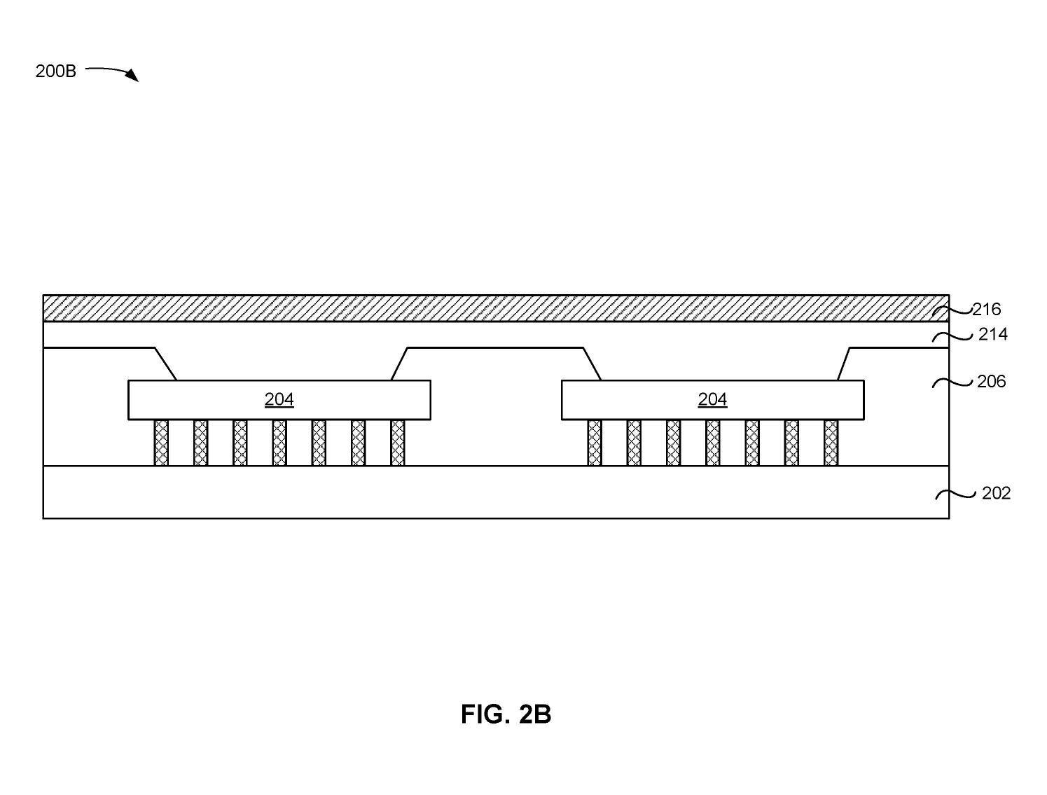

FIG. 2A shows a semiconductor device assembly 200A according to one or more implementations. The semiconductor device assembly 200A may include a circuit substrate 202, one or more semiconductor dies 204, and a package casing 206. The semiconductor device assembly 200A may be similar to the semiconductor device assembly 100A described in connection with FIG. 1A.

The circuit substrate 202 may be a PCB on which the one or more semiconductor dies 204 and the package casing 206 are mounted. Thus, the circuit substrate 202 may include a first substrate surface 202a (e.g., a top substrate surface) and a second substrate surface 202b (e.g., a bottom substrate surface) arranged opposite to the first substrate surface 202a.

The one or more semiconductor dies 204 may be arranged on, and electrically coupled to, the first substrate surface 202a of the circuit substrate 202. Each semiconductor die 204 may include a first die surface 204a (e.g., a top die surface) that faces away from the first substrate surface 202a, a second die surface 204b (e.g., a bottom die surface) that faces toward the first substrate surface 202a, and die edges 204c that extend between the first die surface 204a and the second die surface 204b. In some implementations, multiple semiconductor dies 204 may be formed in one or more die stacks.

The package casing 206, such as a package molding, may be disposed over the circuit substrate 202. For example, the package casing 206 may be disposed over the first substrate surface 202a in order to partially encapsulate each semiconductor die 204 and to protect each semiconductor die 204 from damage and/or warpage. The package casing 206 may encapsulate the die edges 204c and at least part of the first substrate surface 202a of each semiconductor die 204. The package casing 206 may include one or more raised portions 208 that cover an edge region of the first die surface 204a of each semiconductor die 204. Additionally, the first die surface 204a of each semiconductor die 204may include one or more exposed portions 210 (or exposed regions) that are not covered by the package casing 206. The one or more exposed portions 210 may be configured to dissipate heat generated by a semiconductor die 204. In some implementations, the package casing 206 may form a bezel around each semiconductor die 204. In some implementations, the package casing 206 may hook around the die edges 204c of each semiconductor die 204 to extend over the edge region of the first die surface 204a of each semiconductor die 204. In some implementations, the package casing 206 may be formed as a one-piece molding made of a mold compound. Thus, the package casing 206 may protect the die edges 204c and the edge regions of each semiconductor die 204, including corners each semiconductor die 204.

The package casing 206 and the one or more exposed portions 210 may be formed according to an embossed pattern over the first die surfaces 204a of the one or more semiconductor dies 204. For example, the embossed pattern may a windowpane pattern, a waffle pattern, a checkered pattern, or an I-shaped pattern. In some implementations, the one or more exposed portions 210 may be formed over respective hotspots of the one or more semiconductor dies 204 to efficiently dissipate heat from the one or more semiconductor dies 204, while the package casing 206 may be formed over regions of the semiconductor die 204 that are less critical for thermal management. The respective hotspots may correspond to active circuit areas within the one or more semiconductor dies 204. In addition, the package casing 206 may be formed at regions of the one or more semiconductor dies 204to optimize structural support and warpage prevention of the one or more semiconductor dies 204. Thus, the embossed pattern may be configured to optimize or otherwise balance the needs for thermal management, by way of heat dissipation, and structural support and protection.

Additionally, the semiconductor device assembly 200A may include a plurality of conductive structures 212, such as pins, balls, pads, or leads, for each semiconductor die 204. The plurality of conductive structures 212 may be used to mount the second die surfaces 204b of the one or more semiconductor dies 204 to the first substrate surface 202a such that there is a gap between each second die surface 204b and the first substrate surface 202a. The plurality of conductive structures 212 may electrically connect the one or more semiconductor dies 204 to one or more conductive traces of the circuit substrate 102. The plurality of conductive structures 212 may be entirely encapsulated by the package casing 106. For example, the package casing 106 may fill the gaps between the semiconductor dies 204 and the circuit substrate 202 such that the package casing 106 is arranged between each second die surface 204b and the first substrate surface 202a, and encapsulates the conductive structures 212. Thus, the package casing 106 may protect the plurality of conductive structures 212.

As indicated above, FIG. 2A is provided as an example. Other examples may differ from what is described with regard to FIG. 2A.

FIG. 2B shows a semiconductor device assembly 200B according to one or more implementations. The semiconductor device assembly 200B may be similar to the semiconductor device assembly 200A described in connection with FIG. 2A. The semiconductor device assembly 200B may further include a TIM layer 214 and a heat spreader layer 216.

The TIM layer 214 may be arranged over the first die surfaces 204a such that the TIM layer 214 is in contact with the one or more exposed portions 210 of the semiconductor dies 204 and the one or more raised portions 208 of the package casing 206. In some implementations, the TIM layer 214 may be arranged over the one or more raised portions 208 of the package casing 206.

The heat spreader layer 216 may be arranged on the TIM layer 214 such that the TIM layer 214 is arranged between the heat spreader layer 216 and the first die surfaces 204a. Thus, the heat spreader layer 216 may be thermally coupled to the one or more exposed portions 210 of the semiconductor dies 204 by the TIM layer 214. The TIM layer 214 and the heat spreader layer 216 may be configured to receive heat from the one or more exposed portions 210 of the semiconductor dies 204 and move the heat away from the semiconductor dies 204.

As indicated above, FIG. 2B is provided as an example. Other examples may differ from what is described with regard to FIG. 2B.

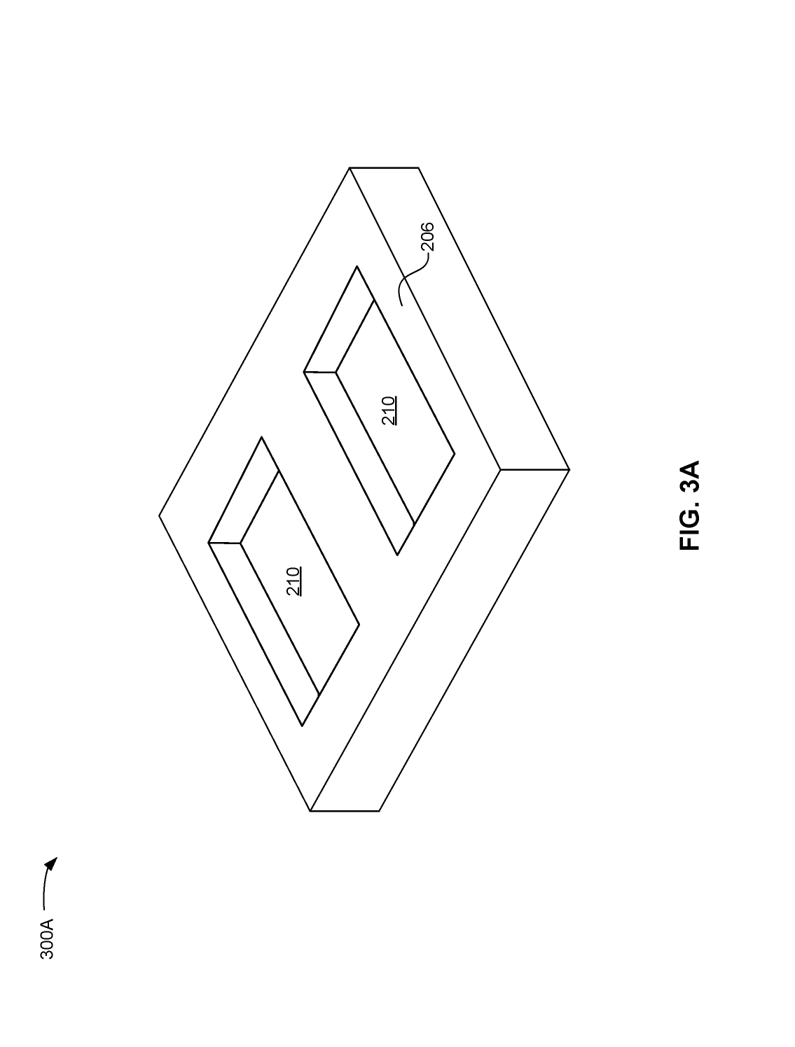

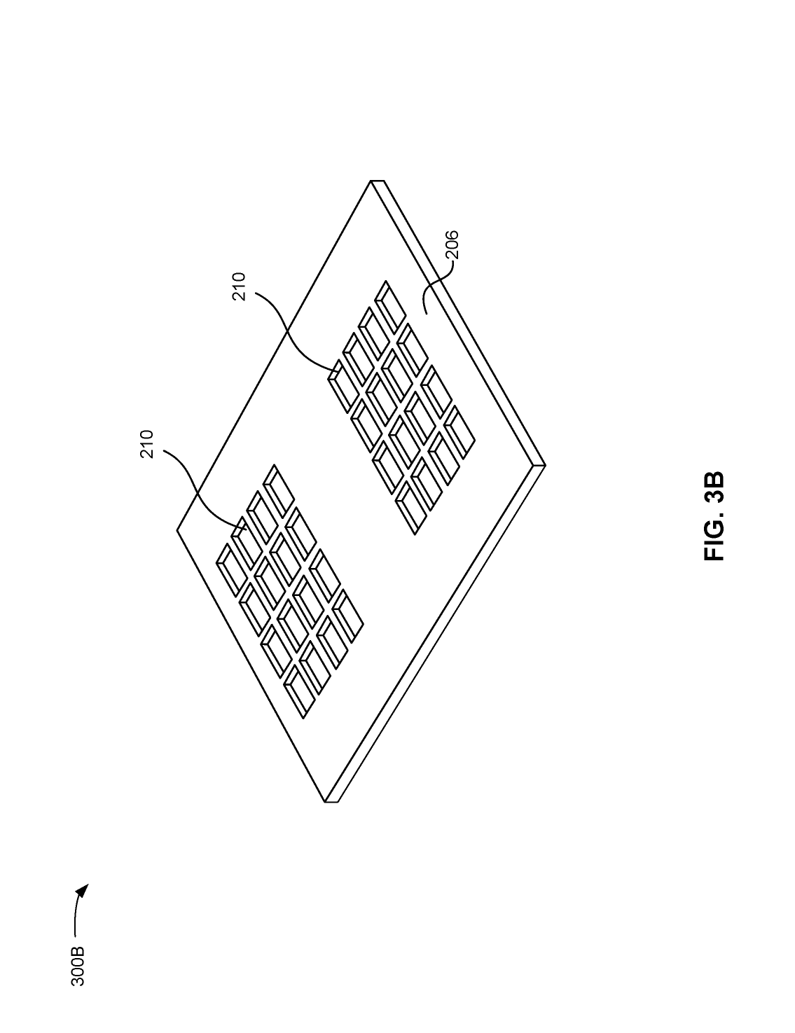

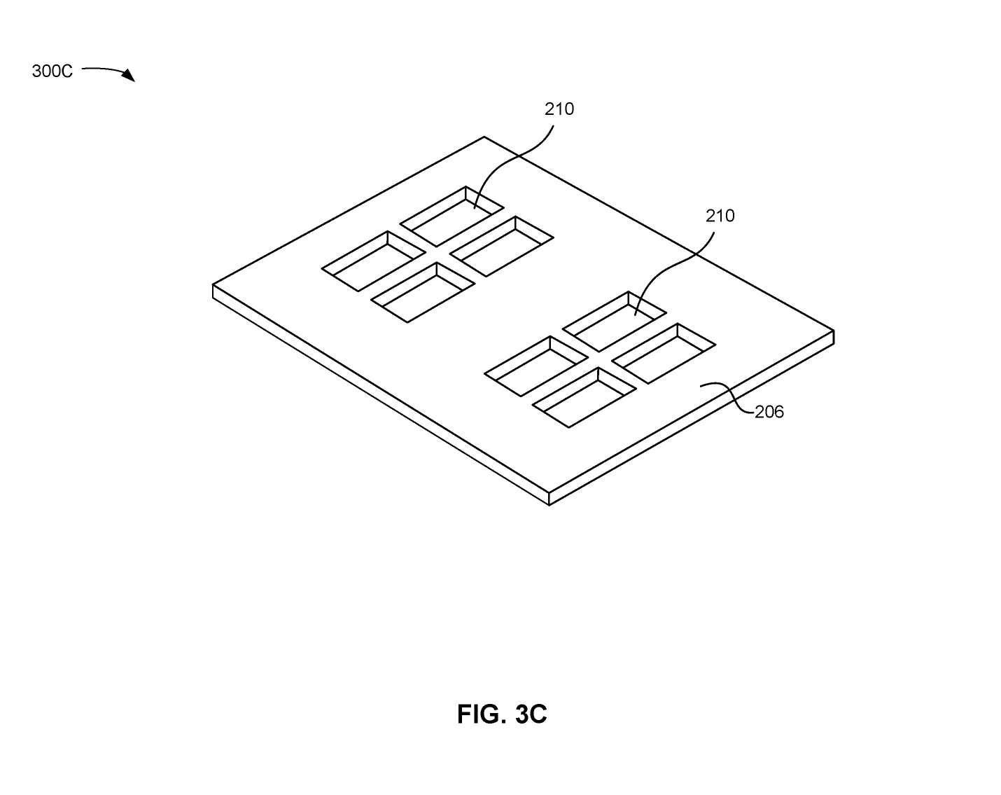

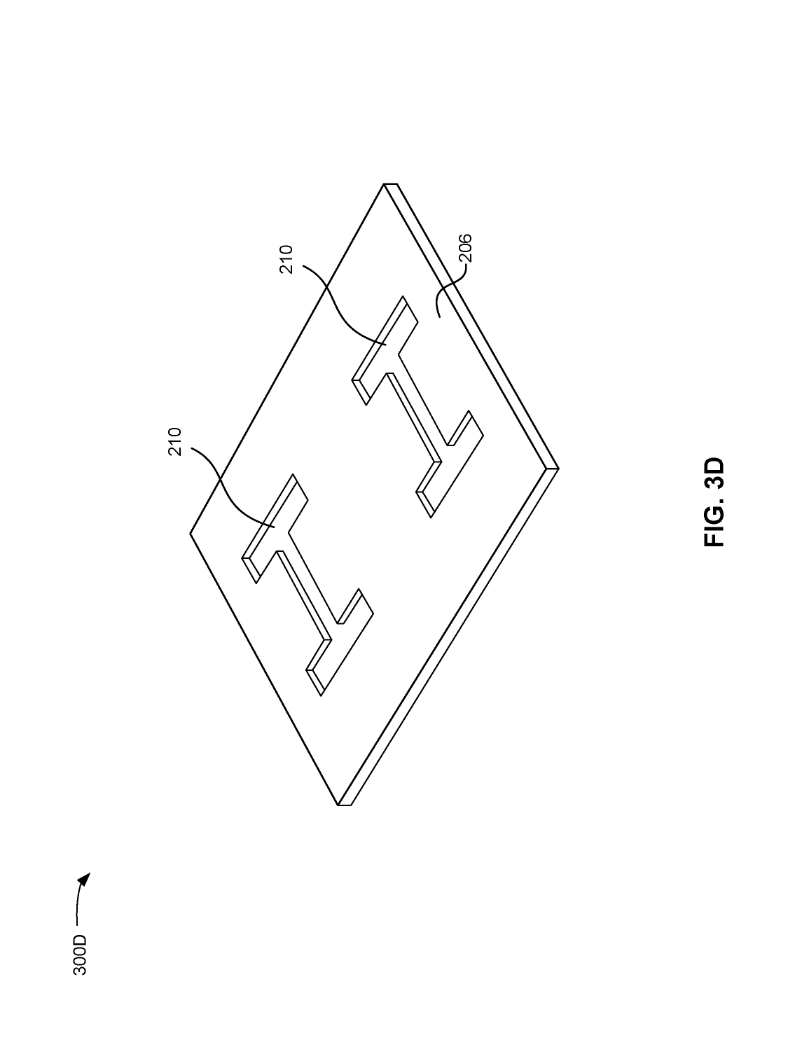

FIG. 3A shows an isometric view of a semiconductor device assembly 300A having an embossed pattern according to one or more implementations. The semiconductor device assembly 300A may be similar to the semiconductor device assembly 200A described in connection with FIG. 2A. The embossed pattern may be formed by a package casing (e.g., package casing 206) and exposed portions (e.g., exposed portions 210). Here, a rectangular exposed portion 210 may be formed over each semiconductor die.

As indicated above, FIG. 3A is provided as an example. Other examples may differ from what is described with regard to FIG. 3A.

FIG. 3B shows an isometric view of a semiconductor device assembly 300B having an embossed pattern according to one or more implementations. The semiconductor device assembly 300B may be similar to the semiconductor device assembly 200A described in connection with FIG. 2A. The embossed pattern may be formed by a package casing (e.g., package casing 206) and exposed portions (e.g., exposed portions 210). Here, exposed portions 210 and package casing material may be patterned with a waffle pattern over each semiconductor die. The waffle pattern may enhance structural support and prevent die or package warpage, while enabling heat to dissipate from the exposed portions 210.

As indicated above, FIG. 3B is provided as an example. Other examples may differ from what is described with regard to FIG. 3B.

FIG. 3C shows an isometric view of a semiconductor device assembly 300C having an embossed pattern according to one or more implementations. The semiconductor device assembly 300C may be similar to the semiconductor device assembly 200A described in connection with FIG. 2A. The embossed pattern may be formed by a package casing (e.g., package casing 206) and exposed portions (e.g., exposed portions 210). Here, exposed portions 210 and package casing material may be patterned with a windowpane pattern over each semiconductor die. The windowpane pattern may enhance structural support and prevent die or package warpage, while enabling heat to dissipate from the exposed portions 210.

As indicated above, FIG. 3C is provided as an example. Other examples may differ from what is described with regard to FIG. 3C.

FIG. 3D shows an isometric view of a semiconductor device assembly 300D having an embossed pattern according to one or more implementations. The semiconductor device assembly 300D may be similar to the semiconductor device assembly 200A described in connection with FIG. 2A. The embossed pattern may be formed by a package casing (e.g., package casing 206) and exposed portions (e.g., exposed portions 210). Here, exposed portions 210 and package casing material may be patterned with an I-shaped pattern over each semiconductor die. The I-shaped pattern may enhance structural support and prevent die or package warpage, while enabling heat to dissipate from the exposed portions 210.

As indicated above, FIG. 3D is provided as an example. Other examples may differ from what is described with regard to FIG. 3D.

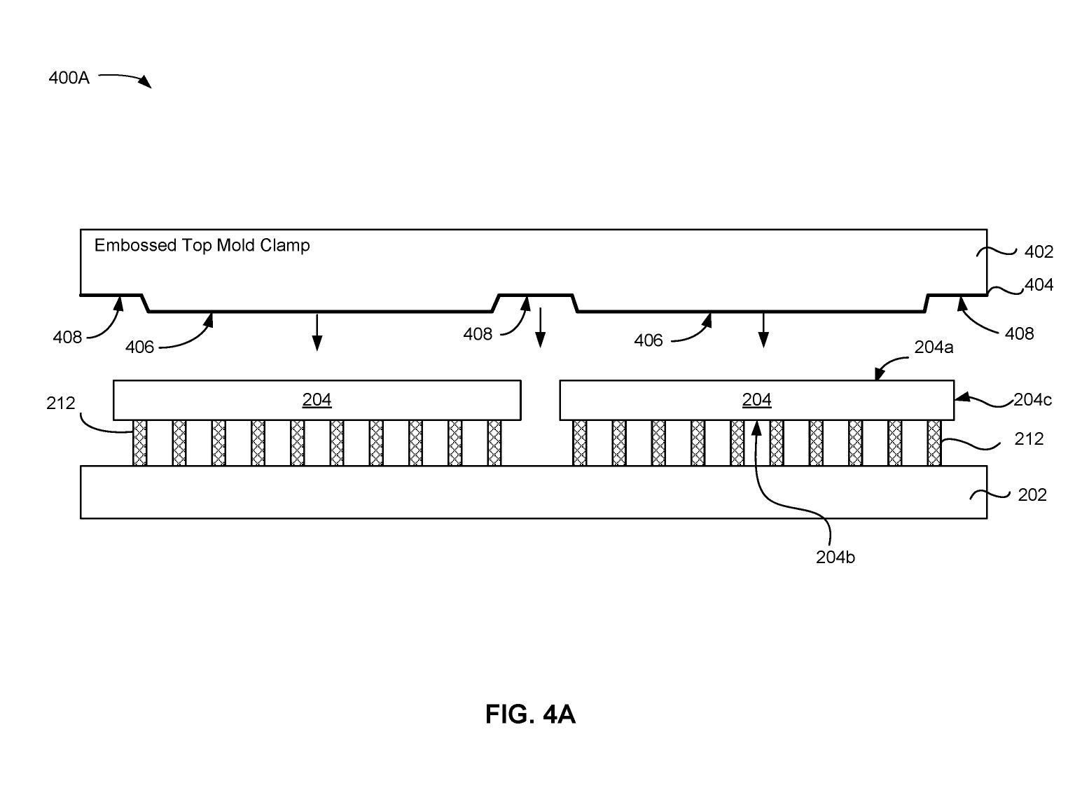

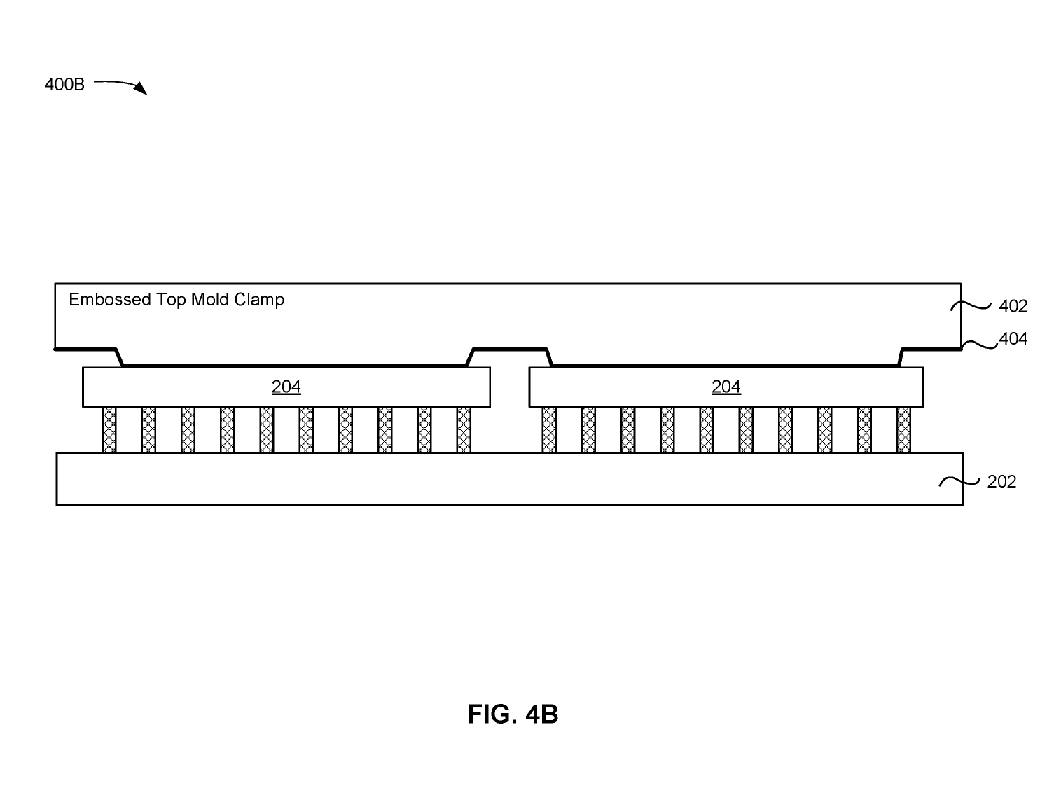

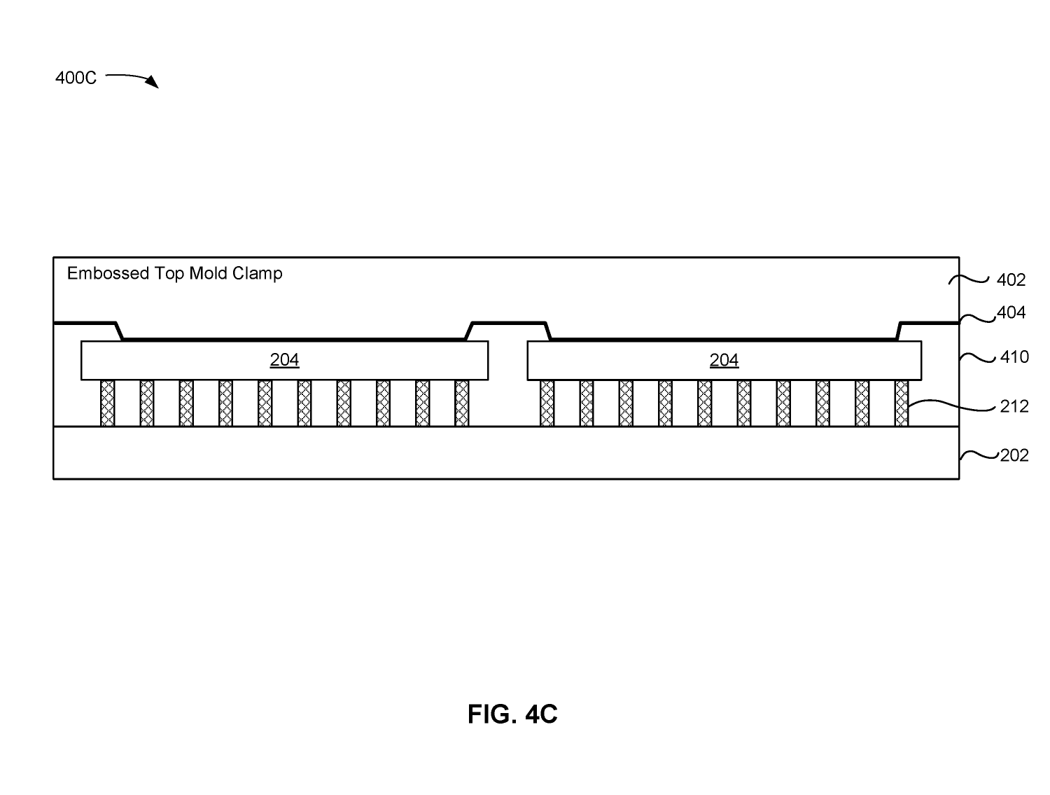

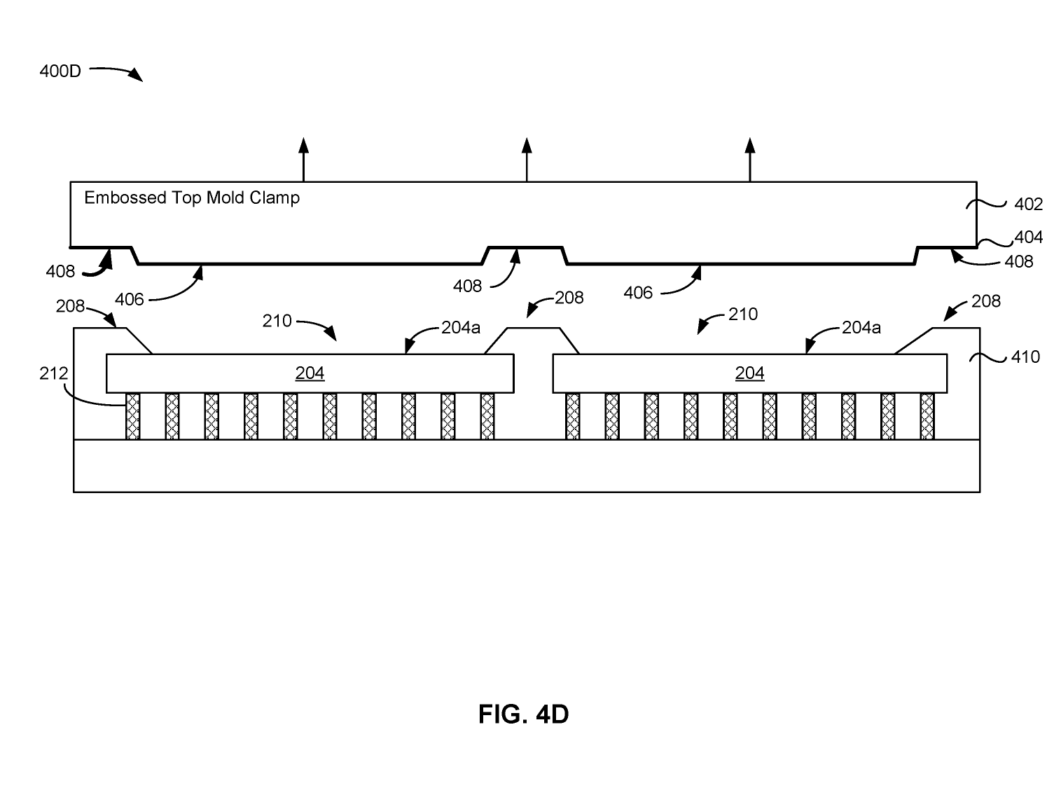

FIGS. 4A-4D show an example process for manufacturing a semiconductor device assembly according to one or more implementations. For example, the example process may be used to manufacture the semiconductor device assembly 200A described in connection with FIG. 2A

FIG. 4A shows a process stage 400A of the example process. The process stage 400A may include arranging one or more semiconductor dies 204 on a circuit substrate 202. Each semiconductor die 204 may have a first die surface 204a that faces away from the circuit substrate 202, a second die surface 204b that faces toward the circuit substrate 202, and die edges 204c that extend between the first die surface 204a and the second die surface 204b, as described above.

Additionally, the process stage 400A may include arranging an embossed mold clamp 402 over the one or more semiconductor dies 204 and the circuit substrate 202. The embossed mold clamp 402 may include a release film 404 that is arranged facing the one or more semiconductor dies 204 and the circuit substrate 202. The release film 404 may be designed and/or configured to make contact with the first die surfaces 204a of the one or more semiconductor dies 204 and easily separate from the first die surfaces 204a of the one or more semiconductor dies 204.

The embossed mold clamp 402 may define an embossed pattern. The embossed mold clamp 402 may include one or more protrusion portions 406, at which one or more exposed portions (e.g., exposed portions 210) are formed, and one or more recessed portions 408, at which the one or more raised portions (e.g., raised portions 208) are formed. Thus, the one or more protrusion portions 406 and the one or more recessed portions 408 may be arranged according to the embossed pattern.

FIG. 4B shows a further process stage 400B of the example process. The process stage 400B may include arranging the embossed mold clamp 402 onto the first die surfaces 204a of the one or more semiconductor dies 204. For example, the embossed mold clamp 402 may be lowered onto the first die surfaces 204a. The embossed mold clamp 402 may be clamped onto the first die surfaces 204a such that the release film 404 forms a seal with the first die surfaces 204a.

FIG. 4C shows a further process stage 400C of the example process. The process stage 400C may include providing, while the embossed mold clamp 402 is arranged on the first die surfaces 204a, a mold compound 410 between the embossed mold clamp 402 and the circuit substrate 202 such that the mold compound 410 encapsulates the die edges 204c and at least part of the circuit substrate 202, and such that the mold compound 410 includes one or more raised portions 208 that cover an edge region of the first die surfaces 204a.

FIG. 4D shows a further process stage 400D of the example process. The process stage 400D may include removing the embossed mold clamp 402 from the first die surfaces 204a such that each first die surface 204a includes one or more exposed portions 210 that are not covered by the mold compound 410. For example, the embossed mold clamp 402 may be lifted off of the first die surfaces 204a. The one or more exposed portions 210 may be configured to release heat generated by the semiconductor dies 204. The one or more exposed portions 210 may be provided at locations at which the embossed mold clamp 402 makes contact with the first die surfaces 204a.

The process stage 400D may include curing the mold compound 410. Thus, the mold compound 410 may form a package casing (e.g., package casing 206) that has the embossed pattern. In other words, the mold compound 410 and the one or more exposed portions 210 may be formed according to the embossed pattern.

In some implementations, the example process may include arranging, after curing the mold compound 410, a TIM layer over the first die surfaces 204a. The TIM layer may be in contact with the one or more exposed portions 210 and the one or more raised portions 208 of the mold compound 410. Additionally, the TIM layer may be arranged over the one or more raised portions 208 of the mold compound 410.

In some implementations, the example process may include arranging a heat spreader layer on the TIM layer such that the TIM layer is arranged between the heat spreader layer and the first die surfaces 204a. The heat spreader layer may be thermally coupled to the one or more exposed portions 210 by the TIM layer.

As indicated above, FIGS. 4A-4D are provided as examples. Other examples may differ from what is described with regard to FIGS. 4A-4D.

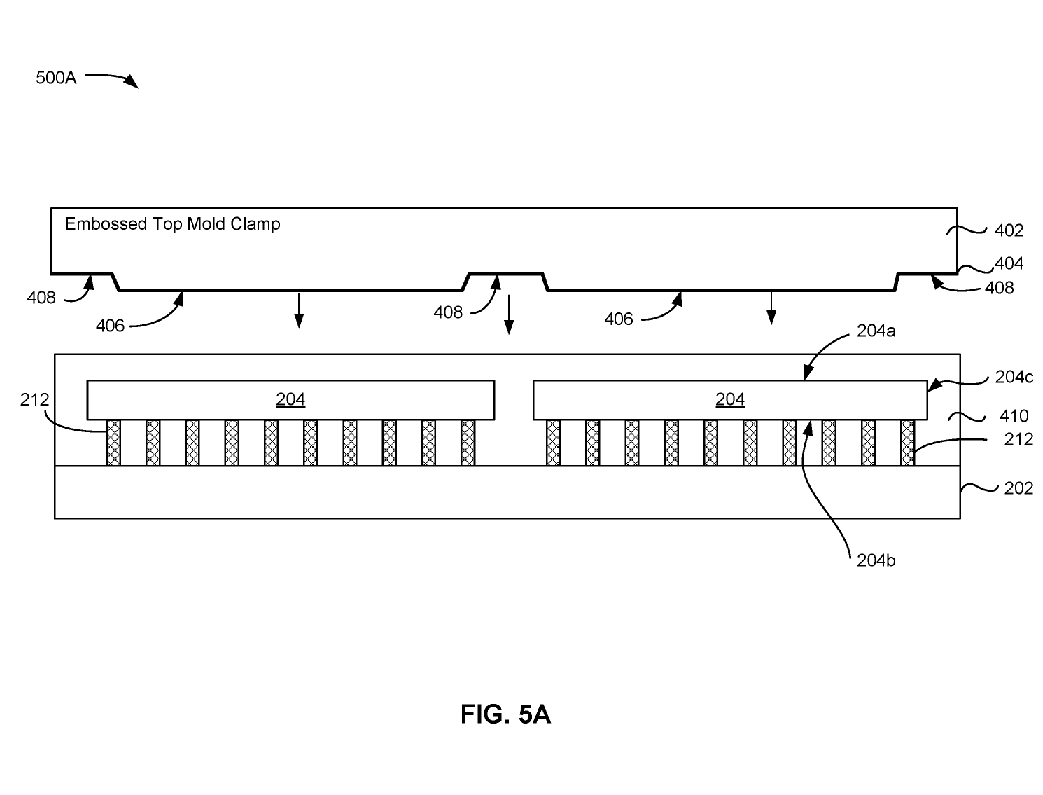

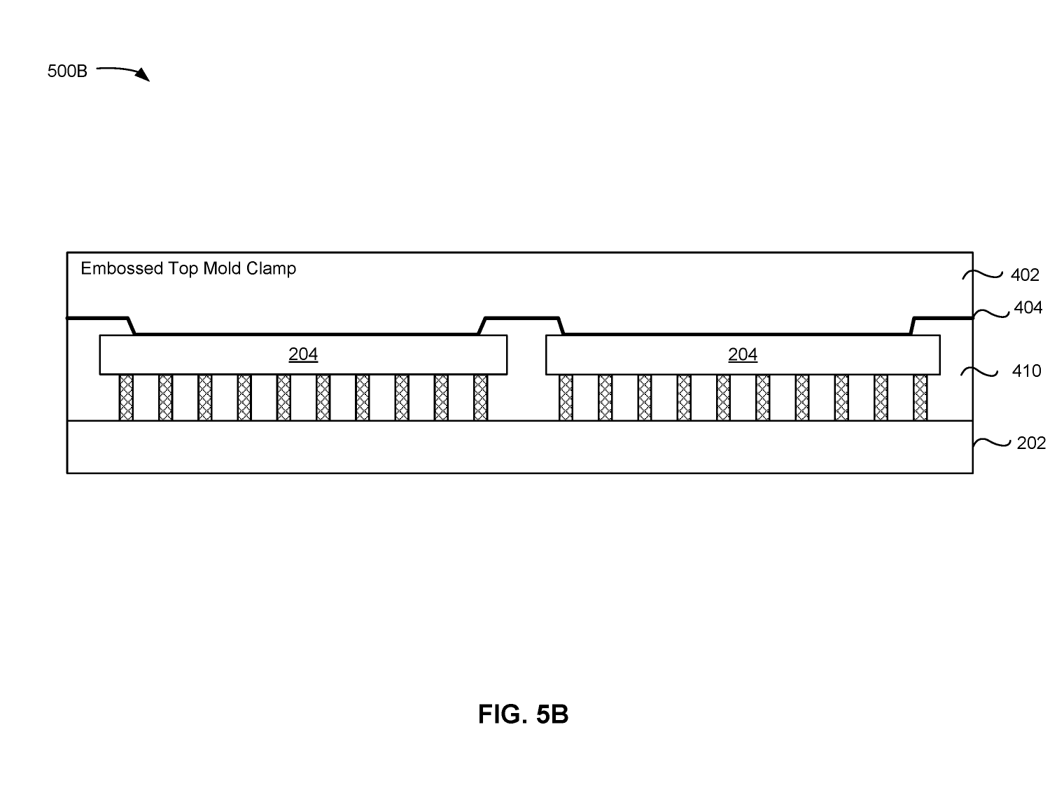

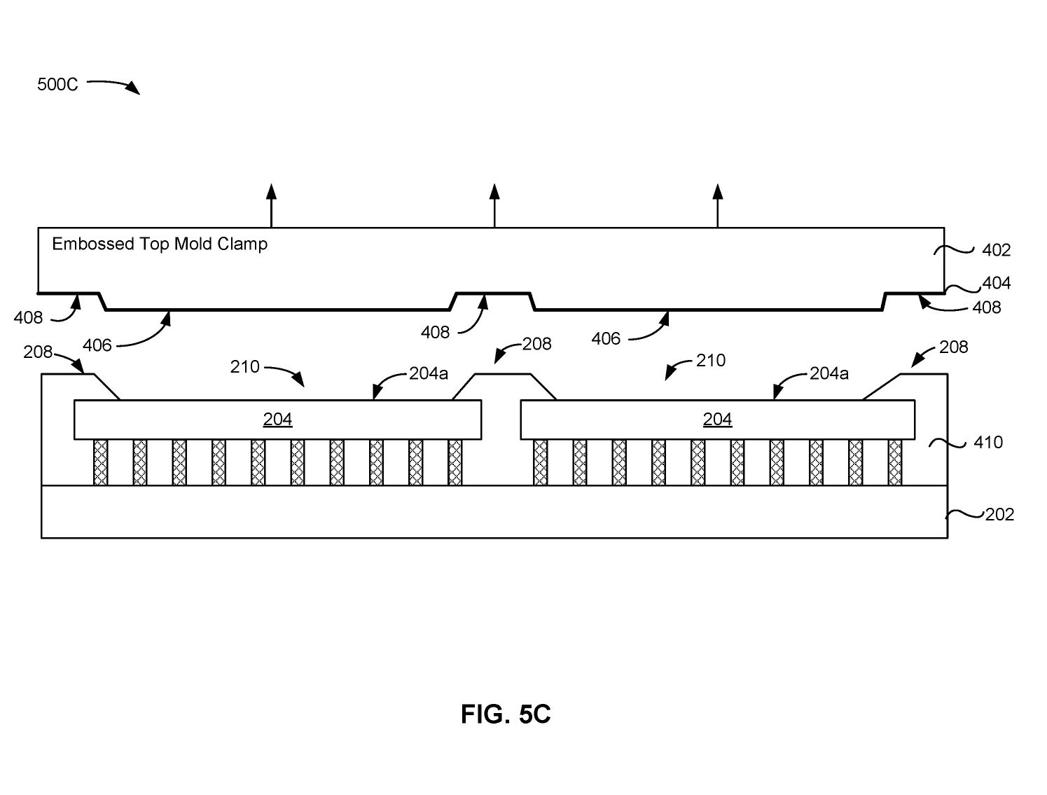

FIGS. 5A-5C show an example process for manufacturing a semiconductor device assembly according to one or more implementations. For example, the example process may be used to manufacture the semiconductor device assembly 200A described in connection with FIG. 2A

FIG. 5A shows a process stage 500A of the example process. The process stage 500A may include arranging one or more semiconductor dies 204 on a circuit substrate 202. Each semiconductor die 204 may have a first die surface 204a that faces away from the circuit substrate 202, a second die surface 204b that faces toward the circuit substrate 202, and die edges 204c that extend between the first die surface 204a and the second die surface 204b, as described above.

The process stage 500A may further include providing a mold compound 410 on the semiconductor dies 204 and on the circuit substrate 202 such that exposed surfaces of the semiconductor dies 204 are fully encapsulated by the mold compound 410.

Additionally, the process stage 500A may include arranging an embossed mold clamp 402 over the one or more semiconductor dies 204 and the circuit substrate 202. The embossed mold clamp 402 may include the release film 404 that is arranged facing the one or more semiconductor dies 204 and the circuit substrate 202. The release film 404 may be designed and/or configured to make contact with the first die surfaces 204a of the one or more semiconductor dies 204 and easily separate from the first die surfaces 204a of the one or more semiconductor dies 204.

FIG. 5B shows a further process stage 500B of the example process. The process stage 500B may include, after the semiconductor dies 204 are encapsulated by the mold compound 410, arranging the embossed mold clamp 402 onto the first die surfaces 204a of the semiconductor dies 204. The embossed mold clamp 402 may include one or more protrusion portions 406 and one or more recessed portions 408 arranged according to an embossed pattern.

The one or more protrusion portions 406 may be configured to push the mold compound 410 away from one or more regions of the first die surfaces 204a and make contact with the one or more regions to form one or more exposed portions 210 on the first die surfaces 204a that are not covered by the mold compound 410. Additionally, the one or more recessed portions 408 may be configured to form the one or more raised portions 208 of the mold compound 410 that cover edge regions of the first die surfaces 204a.

FIG. 5C shows a further process stage 500C of the example process. The process stage 500C may include removing the embossed mold clamp 402 from the first die surfaces 204a such that each first die surface 204a includes one or more exposed portions 210 that are not covered by the mold compound 410 and the mold compound 410 includes the one or more raised portions 208. For example, the embossed mold clamp 402 may be lifted off of the first die surfaces 204a. Thus, the one or more exposed portions 210 may be provided at locations at which the embossed mold clamp 402 makes contact with the first die surfaces 204a. The one or more exposed portions 210 may be configured to release heat generated by the semiconductor dies 204.

The process stage 500C may include curing the mold compound 410. Thus, the mold compound 410 may form a package casing (e.g., package casing 206) that has the embossed pattern. In other words, the mold compound 410 and the one or more exposed portions 210 may be formed according to the embossed pattern.

In some implementations, the example process may include arranging, after curing the mold compound 410, a TIM layer over the first die surfaces 204a. The TIM layer may be in contact with the one or more exposed portions 210 and the one or more raised portions 208 of the mold compound 410. Additionally, the TIM layer may be arranged over the one or more raised portions 208 of the mold compound 410.

In some implementations, the example process may include arranging a heat spreader layer on the TIM layer such that the TIM layer is arranged between the heat spreader layer and the first die surfaces 204a. The heat spreader layer may be thermally coupled to the one or more exposed portions 210 by the TIM layer.

As indicated above, FIGS. 5A-5C are provided as examples. Other examples may differ from what is described with regard to FIGS. 5A-5C.

In some implementations, a semiconductor device assembly includes a circuit substrate comprising a first substrate surface and a second substrate surface arranged opposite to the first substrate surface; a semiconductor die arranged on, and electrically coupled to, the first substrate surface, the semiconductor die having a first die surface that faces away from the first substrate surface, a second die surface that faces toward the first substrate surface, and die edges that extend between the first die surface and the second die surface; and a package casing disposed over the first substrate surface, wherein the package casing partially encapsulates the semiconductor die, wherein the package casing encapsulates the die edges and at least part of the first substrate surface, wherein the package casing includes one or more raised portions that cover an edge region of the first die surface, the edge region of the first die surface being adjacent to the die edges, and wherein the first die surface includes one or more exposed portions that are not covered by the package casing, the one or more exposed portions being configured to dissipate heat generated by the semiconductor die.

In some implementations, a method of manufacturing a semiconductor device assembly includes arranging a semiconductor die on a circuit substrate, the semiconductor die having a first die surface that faces away from the circuit substrate, a second die surface that faces toward the circuit substrate, and die edges that extend between the first die surface and the second die surface; arranging an embossed mold clamp onto the first die surface, wherein the embossed mold clamp defines an embossed pattern; providing, while the embossed mold clamp is arranged on the first die surface, a mold compound between the embossed mold clamp and the circuit substrate such that the mold compound encapsulates the die edges and at least part of the circuit substrate, and such that the mold compound includes one or more raised portions that cover an edge region of the first die surface, the edge region of the first die surface being adjacent to the die edges; removing the embossed mold clamp from the first die surface such that the first die surface includes one or more exposed portions that are not covered by the mold compound, the one or more exposed portions being configured to release heat generated by the semiconductor die; and curing the mold compound, the mold compound having the embossed pattern.

In some implementations, a method of manufacturing a semiconductor device assembly includes arranging a semiconductor die on a circuit substrate, the semiconductor die having a first die surface that faces away from the circuit substrate, a second die surface that faces toward the circuit substrate, and die edges that extend between the first die surface and the second die surface; providing a mold compound on the semiconductor die and on the circuit substrate such that exposed surfaces of the semiconductor die are fully encapsulated by the mold compound; after the semiconductor die is encapsulated by the mold compound, arranging an embossed mold clamp onto the first die surface, wherein the embossed mold clamp includes one or more protrusion portions and one or more recessed portions arranged according to an embossed pattern, wherein the one or more protrusion portions are configured to push the mold compound away from one or more regions of the first die surface and make contact with the one or more regions to form one or more exposed portions on the first die surface that are not covered by the mold compound, and wherein the one or more recessed portions are configured to form one or more raised portions of the mold compound that cover an edge region of the first die surface, the edge region of the first die surface being adjacent to the die edges; removing the embossed mold clamp from the first die surface such that the first die surface includes one or more exposed portions that are not covered by the mold compound and the mold compound includes the one or more raised portions, wherein the one or more exposed portions are configured to release heat generated by the semiconductor die; and curing the mold compound, the mold compound having the embossed pattern.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element’s relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a circuit substrate comprising a first substrate surface and a second substrate surface arranged opposite to the first substrate surface;
a semiconductor die arranged on, and electrically coupled to, the first substrate surface, the semiconductor die having a first die surface that faces away from the first substrate surface, a second die surface that faces toward the first substrate surface, and die edges that extend between the first die surface and the second die surface; and
a package casing disposed over the first substrate surface, wherein the package casing partially encapsulates the semiconductor die,
wherein the package casing encapsulates the die edges and at least part of the first substrate surface,
wherein the package casing includes one or more raised portions that cover an edge region of the first die surface, the edge region of the first die surface being adjacent to the die edges, and
wherein the first die surface includes one or more exposed portions that are not covered by the package casing, the one or more exposed portions being configured to dissipate heat generated by the semiconductor die.

2. The semiconductor device assembly of claim 1, wherein the package casing is configured to protect the die edges and the edge region of the first die surface.

3. The semiconductor device assembly of claim 1, wherein the package casing and the one or more exposed portions are formed according to an embossed pattern over the first die surface.

4. The semiconductor device assembly of claim 3, wherein the embossed pattern is a windowpane pattern, a waffle pattern, a checkered pattern, or an I-shaped pattern.

5. The semiconductor device assembly of claim 3, wherein the one or more exposed portions are formed over respective hotspots of the semiconductor die.

6. The semiconductor device assembly of claim 1, further comprising:
a thermal interface material (TIM) layer arranged over the first die surface, wherein the TIM layer is in contact with the one or more exposed portions and the one or more raised portions of the package casing.

7. The semiconductor device assembly of claim 6, wherein the TIM layer is arranged over the one or more raised portions of the package casing.

8. The semiconductor device assembly of claim 6, further comprising:
a heat spreader layer arranged on the TIM layer such that the TIM layer is arranged between the heat spreader layer and the first die surface,
wherein the heat spreader layer is thermally coupled to the one or more exposed portions by the TIM layer.

9. The semiconductor device assembly of claim 1, further comprising:
a bond wire connected to the edge region of the first die surface and to the first substrate surface,
wherein the second die surface is arranged directly on the first substrate surface, and
wherein the bond wire is entirely encapsulated by the package casing.

10. The semiconductor device assembly of claim 1, further comprising:
a conductive structure configured to mount the second die surface to the first substrate surface such that there is a gap between the second die surface and the first substrate surface,
wherein the package casing fills the gap such that the package casing is arranged between the second die surface and the first substrate surface, and encapsulates the conductive structures.

11. The semiconductor device assembly of claim 1, wherein the package casing is a one-piece molding made of a mold compound.

12. The semiconductor device assembly of claim 1, wherein the package casing hooks around the die edges to extend over the edge region of the first die surface.

13. A method of manufacturing a semiconductor device assembly, the method comprising:
arranging a semiconductor die on a circuit substrate, the semiconductor die having a first die surface that faces away from the circuit substrate, a second die surface that faces toward the circuit substrate, and die edges that extend between the first die surface and the second die surface;
arranging an embossed mold clamp onto the first die surface, wherein the embossed mold clamp defines an embossed pattern;
providing, while the embossed mold clamp is arranged on the first die surface, a mold compound between the embossed mold clamp and the circuit substrate such that the mold compound encapsulates the die edges and at least part of the circuit substrate, and such that the mold compound includes one or more raised portions that cover an edge region of the first die surface, the edge region of the first die surface being adjacent to the die edges;
removing the embossed mold clamp from the first die surface such that the first die surface includes one or more exposed portions that are not covered by the mold compound, the one or more exposed portions being configured to release heat generated by the semiconductor die; and
curing the mold compound, the mold compound having the embossed pattern.

14. The method of claim 13, wherein the one or more exposed portions are provided at locations at which the embossed mold clamp makes contact with the first die surface.

15. The method of claim 13, wherein the mold compound and the one or more exposed portions are formed according to the embossed pattern.

16. The method of claim 13, wherein the embossed mold clamp includes a release film that is in contact with the first die surface.

17. The method of claim 13, further comprising:
arranging, after curing the mold compound, a thermal interface material (TIM) layer over the first die surface, wherein the TIM layer is in contact with the one or more exposed portions and the one or more raised portions of the mold compound.

18. The method of claim 17, wherein the TIM layer is arranged over the one or more raised portions of the mold compound.

19. The method of claim 17, further comprising:
arranging a heat spreader layer on the TIM layer such that the TIM layer is arranged between the heat spreader layer and the first die surface,
wherein the heat spreader layer is thermally coupled to the one or more exposed portions by the TIM layer.

20. The method of claim 13, wherein the embossed mold clamp includes one or more protrusion portions, at which the one or more exposed portions are formed, and one or more recessed portions, at which the one or more raised portions are formed, and
wherein the one or more protrusion portions and the one or more recessed portions are arranged according to the embossed pattern.

21. A method of manufacturing a semiconductor device assembly, the method comprising:
arranging a semiconductor die on a circuit substrate, the semiconductor die having a first die surface that faces away from the circuit substrate, a second die surface that faces toward the circuit substrate, and die edges that extend between the first die surface and the second die surface;
providing a mold compound on the semiconductor die and on the circuit substrate such that exposed surfaces of the semiconductor die are fully encapsulated by the mold compound;
after the semiconductor die is encapsulated by the mold compound, arranging an embossed mold clamp onto the first die surface,
wherein the embossed mold clamp includes one or more protrusion portions and one or more recessed portions arranged according to an embossed pattern,
wherein the one or more protrusion portions are configured to push the mold compound away from one or more regions of the first die surface and make contact with the one or more regions to form one or more exposed portions on the first die surface that are not covered by the mold compound, and
wherein the one or more recessed portions are configured to form one or more raised portions of the mold compound that cover an edge region of the first die surface, the edge region of the first die surface being adjacent to the die edges;
removing the embossed mold clamp from the first die surface such that the first die surface includes one or more exposed portions that are not covered by the mold compound and the mold compound includes the one or more raised portions,
wherein the one or more exposed portions are configured to release heat generated by the semiconductor die; and
curing the mold compound, the mold compound having the embossed pattern.

22. The method of claim 21, wherein the embossed mold clamp includes a release film that is in contact with the first die surface.

23. The method of claim 21, further comprising:
arranging, after curing the mold compound, a thermal interface material (TIM) layer over the first die surface, wherein the TIM layer is in contact with the one or more exposed portions and the one or more raised portions of the mold compound.

24. The method of claim 23, wherein the TIM layer is arranged over the one or more raised portions of the mold compound.

25. The method of claim 23, further comprising:
arranging a heat spreader layer on the TIM layer such that the TIM layer is arranged between the heat spreader layer and the first die surface,
wherein the heat spreader layer is thermally coupled to the one or more exposed portions by the TIM layer.
